(19) United States
(12) Patent Application Publication
(10) Pub. No.: US 2009/0236134 A1
(43) Pub. Date: Sep. 24, 2009

(54) Low frequency ball grid array resonator

(76) Inventors: Thomas A. Knecht, Dundee, IL (US); Glen Reeser, Palatine, IL (US)

Correspondence Address: DANIEL J. DENEUFBOURG;CTS CORPORATION, 171 COVINGTON DRIVE, BLOOMINGDALE, IL, 60108, US

(21) Appl. No.: 12/381,692

(22) Filed: Mar. 16, 2009

Related U.S. Application Data
(60) Provisional application No. 61/070,247, filed on Mar. 20, 2008.

(51) Int. Cl. H05K 1/16

(52) U.S. Cl. 174/260

(57) ABSTRACT

A ball grid array resonator for use as, for example, a high “Q” inductive element in the tank circuit of a voltage controlled oscillator. The resonator comprises a ceramic substrate including opposed top and bottom surfaces, each having a continuous strip of conductive material formed thereon and, in one embodiment, at least two conductive vias which extend through the substrate and electrically interconnect the respective strips of conductive material to define a continuous and elongate path or transmission line for an RF signal. The respective strips of conductive material may be spiral-shaped, hook-shaped, serpentine-shaped, or otherwise suitably shaped depending upon the desired application. Conductive balls/spheres on the bottom surface define RF signal input/output pads and ground pads adapted for electrical connection to the printed circuit board or substrate of, for example, a voltage controlled oscillator.

### CROSS-REFERENCE TO RELATED APPLICATION

This non-provisional application claims the benefit of U.S. Provisional Application Ser. No. 61/070,247 filed on Mar. 20, 2008, the disclosure of which is explicitly incorporated herein by reference as are all references cited therein.

### BACKGROUND OF THE INVENTION

YIG (Yttrium-Iron-Garnet) oscillators, DROs (dielectric resonator oscillators), coaxial resonators, and cavity resonators of the type made and sold by, for example, Dielectric Laboratories Inc. of Cazenovia, N.Y., have been in use for the past several years for the purpose of providing precise frequency control references in products such as voltage controlled oscillators.

Although the above devices have gained acceptance in the marketplace, there remains a need for an RF resonator capable of offering selectivity and other performance improvements at 1.8 GHz or lower, all in a lower cost, smaller, higher performance, and lower height ball grid array type package. This invention provides such an improved ceramic ball grid array type resonator.

### SUMMARY OF THE INVENTION

The resonator of the present invention is adapted for use as a shorted element or high “Q” inductive element in the tank circuit of, for example, a 900 MHz VCO (voltage controlled oscillator) or VCO/PLL (voltage controlled oscillator/phase locked loop).

In one embodiment, the present invention is directed to a ball grid array resonator which initially comprises a ceramic substrate which defines first and second outer opposed surfaces. The resonator further comprises an RF signal transmission line defined by the combination of a first elongate strip of conductive material which is formed on the first surface, a second elongate strip of material which is formed on the second surface, and a conductive via which extends through the substrate and interconnects the first and second strips of material. The resonator still further comprises at least a first conductive ball/sphere on the first surface which defines an RF signal input/output pad in electrical coupling relationship with the first strip of conductive material thereon and a second conductive ball/sphere on the first surface which defines a ground pad.

In accordance with one embodiment of the invention, at least one of the first or second strips of conductive material has a curving pattern such as, for example, a spiral pattern, a serpentine pattern, or a hook-shaped pattern.

Moreover, in accordance with one embodiment of the invention, the RF transmission line further comprises another conductive via which extends through the substrate and is in electrical contact with both the second elongate strip of conductive material and a third conductive ball/sphere on the first surface which defines another RF signal input/output pad.

The respective RF signal input/output balls/spheres and ground balls/spheres are adapted to be seated on and electrically connected to the respective RF signal input/output pads and ground pads on the printed circuit board of an oscillator such as, for example, the tank circuit portion of a voltage controlled oscillator.

Other advantages and features of the present invention will be more readily apparent from the following detailed description of the preferred embodiments of the invention, the accompanying drawings, and the appended claims.

### BRIEF DESCRIPTION OF THE DRAWINGS

These and other features of the invention can best be understood by the following description of the accompanying drawings as follows:

FIG. 1 is an enlarged, top perspective view of one embodiment of a low frequency ball grid array resonator in accordance with the present invention, without a lid;

FIG. 2 is an enlarged, bottom perspective view of the resonator of FIG. 1;

FIG. 3 is an enlarged, top perspective view of another embodiment of a low frequency ball grid array resonator in accordance with the present invention, without a lid;

FIG. 4 is an enlarged, bottom perspective view of the resonator shown in FIG. 3;

FIG. 5 is an enlarged, top perspective view of yet another embodiment of a low frequency ball grid array resonator in accordance with the present invention, without a lid;

FIG. 6 is an enlarged, bottom perspective view of the resonator of FIG. 5;

FIG. 7 is an enlarged, top perspective view of a further embodiment of a low frequency ball grid array resonator in accordance with the present invention, without a lid; and

FIG. 8 is an enlarged, bottom perspective view of the resonator of FIG. 7.

### DETAILED DESCRIPTION OF THE EMBODIMENTS OF THE INVENTION

While this invention is susceptible to embodiments in many different forms, this specification and the accompanying drawings disclose only four respective embodiments of low frequency ball grid array resonators of the present invention. The invention is not intended, however, to be limited to the four embodiments so described.

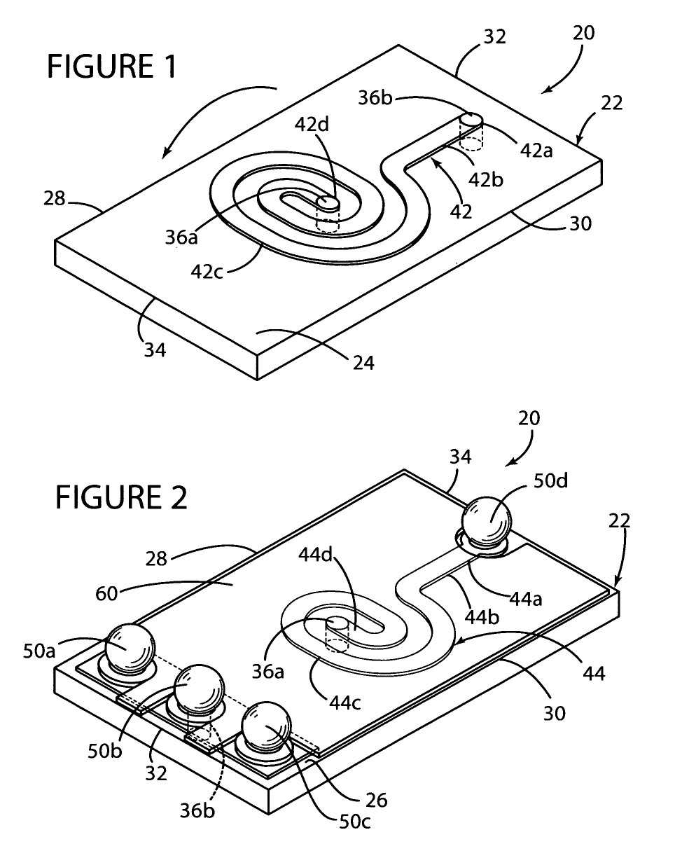

FIGS. 1 and 2 depict a ceramic ball grid array (BGA) microstrip resonator 20 according to the present invention which, in the embodiment shown, measures about 6.0 mm (length)×3.0 mm (width)×1.3 mm (height) (maximum).

Resonator 20 initially comprises a generally rectangularly-shaped substrate or block 22 comprised of any suitable dielectric material that has relatively low loss, a relatively high dielectric constant, and a relatively low temperature coefficient of the dielectric constant. In the embodiment of FIGS. 1-2, substrate 22 is about 20 mils (0.5 mm) thick and is comprised of a ceramic substrate which is about 96% aluminum oxide (Al₂O₃). In the preferred embodiment, substrate 22 has a Q of between about 200-300 and a dielectric constant (K) of about 9.5.

Substrate 22 includes a top surface 24 (FIG. 1), a bottom surface 26 (FIG. 2), and respective side surfaces defining respective long side/longitudinal opposed peripheral edges 28 and 30 and opposed short side/transverse peripheral edges 32 and 34 respectively.

In the embodiment shown, resonator 20 defines at least a pair of generally cylindrically-shaped laser drilled through-holes defining conductive vias 36a and 36b (FIGS. 1 and 2) which are approximately 8 mils (0.20 mm) in diameter and are formed in and extend generally vertically through the body of substrate 22 between, and in a relationship generally normal to, the top and bottom surfaces 24 and 26 respectively. Vias 36a and 36b terminate in, and define via termination apertures/ends in both the top and bottom surfaces 24 and 26 respectively of the substrate 22.

In the embodiment of FIGS. 1 and 2, via 36a is preferably centrally located on substrate 22 while via 36b is located centrally adjacent the edge 32 of substrate 22 in a relationship generally co-linear with via 36a.

Although not shown in any of the FIGURES, it is understood that the vias 36a and 36b are defined by respective through-holes which have been filled with a suitable and conventional thick film conductive via fill material, such as a Ag/Pd (silver/palladium) composition comprising about 99% silver and 1% palladium; having a conductivity of about 4.3×10⁷ mho/cm; a resistivity of about 2.3 μohm-cm; and a sheet resistance of about 2.2 ohm/square.

A plurality of solder spheres or balls 50a-50d (FIG. 2), each with a pitch of a minimum of about 1.0 mm and a diameter of about 0.025 inches (0.64 mm), are mechanically and electrically attached to the bottom surface 26 of substrate 22. Spheres 50a-50d are composed of any suitable high temperature solderable material which does not reflow or change shape such as, for example, a 90% Pb and 10% Sn composition (or a lead-free copper with Sn/Ni plating composition if desired) and are adapted to allow the direct surface mounting of the resonator 20 to the printed circuit board of, for example, a GSM base station. Although not described in detail herein or shown in any of the drawings, it is understood that the spheres 50a-50d could also take the form of pads or strips of conductive material.

In the embodiment shown, substrate 22 includes four spheres 50a, 50b, 50c, and 50d attached to the surface 26 of substrate 22 (FIG. 1). Spheres 50a, 50b, and 50c extend in a spaced-apart relationship along and adjacent the edge 32 of substrate 22. Sphere 50b is attached to and overlies the end of via 36b which terminates in bottom substrate surface 26. Sphere 50d is located generally centrally on the substrate 22 adjacent substrate edge 34 in a relationship generally co-linear with via 36a and diametrically opposed to sphere 50b.

The solder spheres 50a and 50c define respective ground pins or pads adapted to be electrically connected to the respective ground pads of the external printed circuit board to which the resonator 20 is adapted to be direct surface mounted.

Solder spheres 50b and 50d define the RF signal input/output pins or tap pads of resonator 20 and are adapted for electrical coupling to the respective RF signal input/output pads of the external printed circuit board (not shown) to which the resonator 20 is adapted to be direct surface mounted.

The top and bottom surfaces 24 and 26 of resonator 20 additionally define respective conductive metallization resonator patterns 42 and 44 (FIGS. 1 and 2), each defined by an elongate unitary strip of conductive material which has been formed on the top and bottom surfaces 24 and 26 of substrate 22 by any suitable technique including, but not limited to, conventional thick film conductor processing techniques or conventional ablation techniques. Each of the resonator strips is likewise comprised of a suitable and conventional Ag/Pd conductive thick film material similar in composition to the material in vias 36a and 36b.

Elongate resonator strip 42 on top surface 24 defines a first end 42a coupled to and surrounding the termination end of via 36b defined in the top surface 24 of substrate 22. Strip 42 additionally defines a generally straight segment 42b which extends generally centrally on top surface 24 downwardly away from via 36b in a relationship parallel to long side substrate peripheral edges 28 and 30; and a generally centrally located “3.5 turn” curved spiral segment 42c defining a spiral end 42d which is electrically coupled to and surrounds the termination end of via 36a protruding in surface 24.

Elongate resonator strip 44, which is oriented and positioned on bottom surface 26 in a relationship diametrically opposed to resonator strip 42 on top surface 24, defines a first end 44a which is electrically coupled to and surrounds sphere 50d; a generally straight segment 44b which extends generally centrally on substrate surface 26 downwardly away from the sphere 50d and end 44a in a relationship parallel to long side substrate peripheral edges 28 and 30; and a generally centrally located “2.5 turn” curved spiral segment 44c defining a spiral end 44d which is electrically coupled to and surrounds the termination end of via 36a which protrudes into surface 26. In the embodiment shown, spiral segment 44c of strip 44 has a smaller diameter than spiral segment 42c of strip 42.

Thus, in accordance with the present invention, it is understood that an RF signal is adapted to be transferred and passed from the RF input pad (not shown) of a customer's printed circuit board (not shown) to either the sphere 50d or the sphere 50b of resonator 20 since either may comprise an RF signal input. In the application where the RF signal is inputted through the sphere 50d sifting atop strip end segment 44a, the RF signal flows successively from sphere 50d, downwardly through strip segments 44a, 44b, and 44c of strip 44, then upwardly through the interior of substrate 22 through via 36a, then successively through strip segments 42c, 42b, and 42a of strip 42, then back down through the interior of substrate 22 through via 36b into sphere 50b, and finally into the RF signal output pad (not shown) of the printed circuit board or substrate of, for example, a voltage controlled oscillator module (not shown).

Thus, in accordance with the present invention, elongate resonator strips 42 and 44 in combination with the substrate vias 36a and 36b and the spheres 50b and 50d together define an elongate, continuous RF signal transmission line/pathway/strip/pattern extending through the resonator 20.

The frequency of the RF signal passing through the resonator 20 is dependent in part upon the length and configuration of resonator strips 42 and 44. The length, of course, can be increased or decreased, for example, by increasing or decreasing the number of turns in the respective curved spiral segments of each of the respective resonator strips 42 and 44 and/or increasing or decreasing the length of the respective straight segments 42b and 44b and/or increasing or decreasing the width of the respective strips 42 and 44.

For example, it is understood that a shortening or decrease in the length of strips 42 and 44 will result in a corresponding increase in the effective frequency of resonator 20, while an increase in the length of one or both of the strips 42 and 44 will result in a corresponding decrease in the effective frequency of the resonator 20. This frequency is generally the quarter wavelength frequency of the resonator. The desired frequency and application for resonator 20 will, of course, determine the respective effective lengths of strips 42 and 44.

Although not shown in any of the FIGURES, it is further understood that resonator 20 may additionally comprise an optional metal lid which may be about 20 mils (0.5 mm high), adapted to be seated over and secured to the top surface 24 of substrate 22 and provide several functions including: providing an air gap above the resonator strip pattern 42; functioning as a Faraday shield; defining a ground plane above resonator strip pattern 42; and acting as a dust cover for resonator 20.

Resonator 20 is preferably assembled using the following process sequence: A substrate 22 is provided and the through-holes/vias are laser-drilled therethrough. Via fill material paste is then screened over each of the through-hole openings. Both of the surfaces 24 and 26 of the substrate 22 are then rolled to force the fill material through the through-holes to define the vias 36a and 36b. Substrate 22 is then fired in an oven at approximately 850° C. to cure the via fill material.

Resonator conductive strip patterns 42 and 44 are then subsequently formed on the top and bottom surfaces 24 and 26 of substrate 22 as by, for example, a screening or plating process or an ablative process followed by firing in an oven at about 850° C. to cure the Ag/Pd conductive material.

A generally translucent optional protective coating or masking layer of dielectric material called a glasscoat may then be screen printed over the portion of the top and bottom surfaces 24 and 26 of the substrate 22 and the substrate 22 is again fired in an oven at about 850° C. to cure the coat layer of dielectric material. FIG. 2 shows glasscoat layer 60. This coating is not optional on the bottom surface 26, as it defines the positions of the solder balls.

Solder paste is then screen printed over the top surface 22 in the region adjacent each of the side edges thereof and the optional lid (not shown) may be seated over the top surface 24 of substrate 22. The solder is then reflowed to secure the optional lid to the substrate 22.

Solder paste (not shown) is also screen printed on the bottom surface 26 of substrate 22 (see FIG. 2) in the regions thereof where conductive spheres 50a-50d are adapted to be seated. All of the conductive spheres 50a-50d are then seated over each of the points of solder paste and the solder paste is subsequently reflowed for permanently securing the solder spheres 50a-50d to the substrate 22.

Finally, resonator 20 is tested and then taped and reeled for shipment.

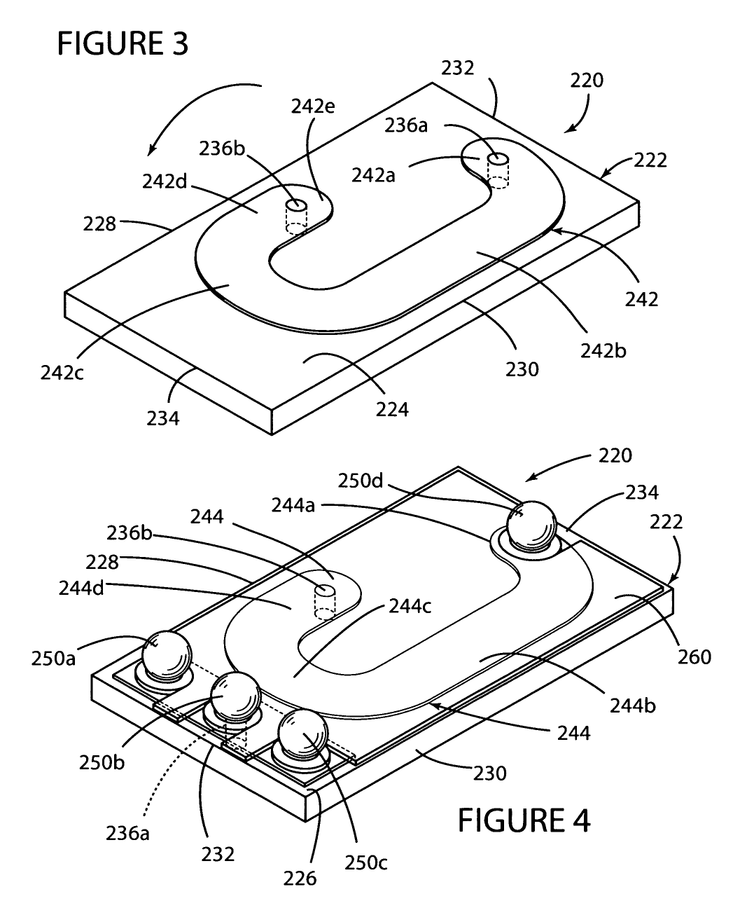

FIGS. 3 and 4 depict a second resonator embodiment 220 in accordance with the present invention.

Initially, and as described earlier with respect to the resonator embodiment 20, resonator 220 likewise initially comprises a generally rectangularly-shaped substrate or block 222 which preferably has the same dimensions and composition as the substrate 22 and thus the earlier discussion and description with respect to substrate 22 is hereby incorporated herein by reference.

Substrate 222 includes a top surface 224 (FIG. 3), a bottom surface 226 (FIG. 4) adapted to face the top of the printed circuit board (not shown) on which the resonator 220 is adapted to be seated and direct surface mounted, and side surfaces defining long side/longitudinal peripheral edges 228 and 230 and short side/transverse peripheral edges 232 and 234 respectively.

Resonator 220 further includes a pair of elongate laser drilled through-holes defining conductive vias 236a and 236b which extend through the body/interior of the substrate 222 and terminate in respective apertures/openings in the top and bottom substrate surfaces 224 and 226. Vias 236a and 236b extend through the substrate 222 in a generally normal relationship relative to the top and bottom substrate surfaces 224 and 226.

In the embodiment of FIGS. 3 and 4, via 236a is generally centrally located and formed adjacent to and spaced from the short side substrate edge 232 while via 236b is generally centrally located and formed adjacent to and spaced from the long side substrate edge 228. Vias 236a and 236b are filled with the same Ag/Pd material as described above with respect to vias 36a and 36b of resonator 20 and thus the earlier description is incorporated herein by reference.

In a manner similar to resonator embodiment 20, resonator 200 likewise includes conductive solder spheres 250a, 250b, 250c, and 250d (similar in size and composition to spheres 50a-50d, the description of which is thus incorporated herein by reference) positioned and secured to the bottom surface 226 of substrate 222. Specifically, spheres 250a, 250b, and 250c are aligned and extend along and adjacent the short side substrate edge 232 in a generally co-linear, spaced-apart relationship with sphere 250b overlying via 236b. Sphere 250d is generally centrally located along opposed short side substrate edge 234 in a relationship diametrically opposed to and co-linear with sphere 250b.

Moreover, and as shown in FIGS. 3 and 4, each of the surfaces 224 and 226 of substrate 222 defines respective elongated conductive thick film resonator metallization pattern or strips 242 and 244 similar in composition to resonator metallization strips 42 and 44 of resonator 20, the description of the composition of each of such strips thus being incorporated herein by reference as though fully described except as otherwise described below.

Resonator strip 242 is generally curved and, more specifically, hook-shaped and is defined by one proximal curvilinear end 242a which is electrically coupled to and surrounds the aperture/end of via 236a terminating in substrate surface 224; a generally straight segment 242b extending generally downwardly away from via 236a in a relationship and orientation generally parallel, spaced from, and adjacent to longitudinal long side substrate edge 230; a hook portion/segment 242c defining a curvilinearly-shaped base portion disposed generally adjacent and spaced from substrate short side edge 234 and extending in the direction of substrate long side edge 228; and a terminal straight portion/segment 242d which extends generally upwardly away from base portion 242c in the direction of substrate short side edge 232 in a relationship spaced from and generally parallel to long side substrate edge 228 and terminating in a distal end 242e which is electrically coupled to the end/aperture of via 236b terminating in substrate surface 224.

Resonator strip 244 which has the same curved, hook-shaped configuration as resonator strip 242, and is positioned and oriented on surface 226 in a relationship diametrically opposed to resonator strip 242 on surface 224, is defined by one proximal end 244a which is electrically coupled to and surrounds the sphere 250d; a generally straight segment 244b extending generally downwardly away from sphere 250d in a relationship and orientation generally parallel, adjacent to, and spaced from long side substrate edge 230; a hook portion/segment 244c defining a curvilinearly-shaped base portion disposed generally adjacent and spaced from substrate short side edge 232 and spheres 250a-250c and extending in the direction of substrate long side edge 228; a terminal straight portion/segment 244d which extends generally upwardly away from base portion 244c in the direction of substrate short side edge 234 in a relationship spaced from, adjacent to, and generally parallel to long side substrate edge 228; and a terminal end 244f which is electrically coupled to and surrounds the end/aperture of via 236b terminating in bottom surface 226. FIG. 4 shows glasscoat layer 260, similar to glasscoat layer 60 of resonator 20, formed over strip 244 and surface 226 of resonator 220.

Thus, in view of the above, and as explained above with resonator embodiment 20, it is understood that the formation and use of elongate resonator strips 242 and 244 on opposed substrate surfaces 224 and 226 in coupling electrical relationship with respective vias 236a and 236b and spheres 250b and 250d defines a continuous elongate RF signal transmission line/pathway/strip/pattern extending through the resonator 220 which makes the resonator 220 particularly suited and adapted for low frequency applications, i.e., applications in the range below about 1.8 GHz.

Moreover, in the resonator embodiment 220 of FIGS. 3 and 4, respective resonator strips 242 and 244 have a width which is generally about one quarter the width of the resonator 220 or about twice the width of each of the resonator strips 42 and 44 of resonator embodiment 20. It is understood, of course, that increasing the width of the resonator strips results in a resonator with increased or heightened “Q” value since resistance decreases in proportion to an increase in the width of a conductive element.

In accordance with this embodiment of the invention and referring to FIGS. 3 and 4, the RF signal is adapted to pass successively from the RF input pad on the PCB (not shown) into and through either the solder sphere 250b or 250d depending upon the application. Solder spheres 250b and 250d both define respective RF signal input/output pads. In the application where the RF signal is inputted through the sphere 250d sitting atop end strip portion 244a of resonator of resonator strip 244, the RF signal passes from the sphere 250d and then through the resonator strip 244 in a generally clockwise direction through the length of resonator strip 244; then upwardly through the interior of substrate 222 through via 236b; then generally counter-clockwise through the length of resonator strip 242 on top surface 224; and then back down and through the interior of board substrate 222 through via 236a into sphere 250b and into the RF signal output pad (not shown) of a printed circuit board.

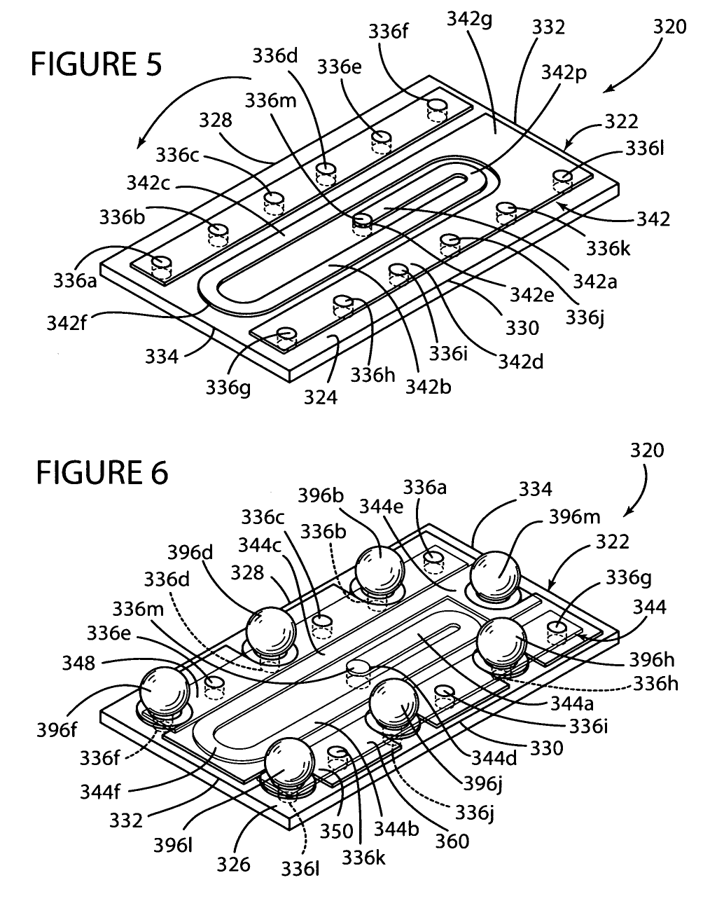

FIGS. 5-6 depict yet another low frequency resonator embodiment 320 in accordance with the present invention.

Initially, and as described earlier with respect to the resonator embodiments 20 and 220, resonator 320 likewise initially comprises a generally rectangularly-shaped substrate or block 322 having the same dimensions and composition as the substrates 22 and 222 and thus the earlier discussion and description relating to substrates 22 and 222 is expressly hereby incorporated herein by reference.

Substrate 322 includes a top surface 324 (FIG. 5), a bottom surface 326 (FIG. 6) adapted to face the top of a printed circuit board or substrate such as, for example, the tank circuit portion of the printed circuit board or substrate of a voltage controlled oscillator (not shown) on which the resonator 320 is adapted to be seated and direct surface mounted, and side surfaces defining long side/longitudinal peripheral edges 328 and 330 and short side/transverse peripheral edges 332 and 334 respectively.

A plurality of elongate laser drilled through-holes defining conductive vias 336a-m (FIGS. 5 and 6) extend through the body/interior of the substrate 322 and terminate in the top and bottom surfaces 324 and 326 respectively of the substrate 322. Vias 336a-m extend through the substrate 322 in a generally normal relationship relative to the top and bottom substrate surfaces 324 and 326. More specifically, it is understood that each of the vias 336a-m terminate in and define respective termination ends in respective portions of substrate surfaces 324 and 326. Vias 336a-m are filled with the same type of conductive material as described above with respect to vias 36a and 36b of resonator 20 and thus the earlier description is incorporated herein by reference.

As shown in FIGS. 5 and 6, vias 336a-f extend in a spaced-apart and co-linear relationship along, spaced from, and adjacent to, long side substrate peripheral edge 328 while vias 336g-l extend in a spaced-apart and co-linear relationship along, spaced from, and adjacent to, opposed long side substrate peripheral edge 330. Vias 336a-f and vias 336g-l are diametrically opposed to each other. Via 336m is generally centrally located on substrate 322.

A total of seven solder spheres/balls 396b, 396d, 396f, 396h, 396j, 396l, and 396m are secured to the bottom surface 326 of substrate 322 as shown in FIG. 6. Solder spheres 396b, 396d, 396f, 396h, 396j, and 396l are seated over and secured to the respective filled ends of respective vias 336b, 336d, 336f, 336h, 336j, and 336l terminating in substrate bottom surface 326. In the embodiment shown, all of the respective solder balls/spheres overlying the respective termination ends of the respective vias 336 define respective ground pins adapted to be positioned in direct surface contact with the respective ground pads of an external printed circuit board (not shown) to which the resonator 322 is adapted to be direct surface mounted.

Solder ball/sphere 396m is located generally centrally along, spaced from, and adjacent to the short side substrate edge 334 and defines the input RF signal pin or pad of resonator 322 adapted for direct surface mount contact with the respective input RF signal pad of the external printed circuit board (not shown) on which the resonator 322 is adapted to be direct surface mounted.

Resonator 320 likewise comprises respective resonator strip patterns 342 and 344 (FIGS. 5 and 6) defined on opposed substrate surfaces 324 and 326 respectively which have been formed thereon in a manner similar to that as described earlier with respect to the resonator strip pattern of resonator embodiments 20 and 220 above, the description of which is thus incorporated herein by reference.

As shown in FIG. 5, continuous, elongate resonator strip pattern 342 is generally curved and, more specifically, “serpentine”-shaped and includes respective spaced-apart, generally parallel, elongate, spaced-apart and straight serpentine strip segments/portions 342a, 342b, 342c, and 342d which extend between and in a relationship generally spaced from and parallel to longitudinal side substrate edges 328 and 330. Strip 342a is generally centrally located on the substrate surface 324 and defines a termination end 342e in electrical contact with and surrounding the end of via 336m which terminates in substrate surface 324. Strip 342d overlies, and is in electrical contact with, the vias 336g-336l which extend along the longitudinal side substrate edge 330. Strip 342b is located between strips 342a and 342d. Respective curvilinearly-shaped segments 342e, 342f, and 342g couple the straight segments 342a, 342b, 342c and 342d to each other.

The top substrate surface 324 additionally defines a separate elongate straight strip of conductive material 346 which extends along, is spaced from, and parallel to, the long side substrate edge 328 in a relationship overlying, and in electrical contact with, the ends of vias 336a-336f terminating in surface 324. Strip segment 342b of resonator strip pattern 342 is positioned between strip 346 and strip 342a and strip 346 is positioned in diametrically opposed relationship to the strip segment 342d of serpentine strip pattern 342.

As shown in FIG. 6, continuous, elongate resonator strip pattern 344, which is positioned and oriented on surface 326 in a relationship diametrically opposed to resonator strip pattern 342 on surface 324, is generally centrally located on bottom substrate surface 326, is generally also curved and, more specifically, “serpentine”-shaped, and includes respective spaced-apart, generally parallel elongate serpentine straight segments/portions 344a, 344b, and 344c all extending in a relationship generally parallel to long side substrate peripheral edges 328 and 330. Respective curvilinearly-shaped segments 344e and 344f couple the straight serpentine segments 344a, 344b, and 344c to each other.

Central serpentine segment 344a defines a terminal end 344d in electrical coupling relationship with and surrounding the end of central via 336m which terminates in the substrate surface 326 while outer serpentine segment 344c defines a terminal end or pad 344e in electrical coupling relationship with the sphere 396m disposed adjacent short side substrate edge 334.

The bottom surface 326 still further defines a pair of additional elongate, generally straight strips of conductive material 348 and 350 which are separate (i.e., not electrically connected to) any of the strips of resonator strip pattern 344. Strip 348 extends along and spaced from the long substrate side edge 328 in a relationship overlying the ends of the vias 336a-336f and in relationship spaced from and parallel to the strip 344c of resonator strip pattern 344. Strip 350 is diametrically opposed to strip 348 and extends along the opposed long substrate side edge 330 in a relationship overlying the ends of the vias 336g-336l and in a relationship spaced from and parallel to the strip 344b of resonator strip pattern 344. FIG. 6 shows glasscoat layer 360, similar to glasscoat layer 60 of resonator 20, formed over the strip 344 and surface 326 of resonator 320.

Thus, in accordance with this embodiment of the invention and referring to FIGS. 5 and 6, the RF signal is adapted to pass from the RF signal input pad on the printed circuit board of, for example, a voltage controlled oscillator (not shown) into and through the RF signal input/output solder sphere or pad 396m seated on bottom substrate surface 326; then through each of the strips 344c, 344b, and 344a of serpentine resonator pattern 344 on bottom surface 326; then upwardly through the interior of substrate 322 and, more particularly, via 336m; then successively through each of the strips 342a, 342b, 342c, and 342d of serpentine resonator pattern 342 on the top surface 324; then downwardly back through the interior of the substrate 322 through respective vias 336g-336l; then through respective solder spheres 396h, 396j, and 396l; and then into the respective ground pads (not shown) of an oscillator printed circuit board.

As with the earlier resonator embodiments 20 and 220, it is understood that the use of serpentine resonator strip patterns 342 and 344 on both surfaces 324 and 326 of resonator 320 in coupling relationship with respective through-hole vias advantageously defines an elongate and continuous conductive resonator transmission pathway/strip/pattern which makes resonator 320 particularly suitable and adapted for low frequency applications in the range below about 1.8 GHz.

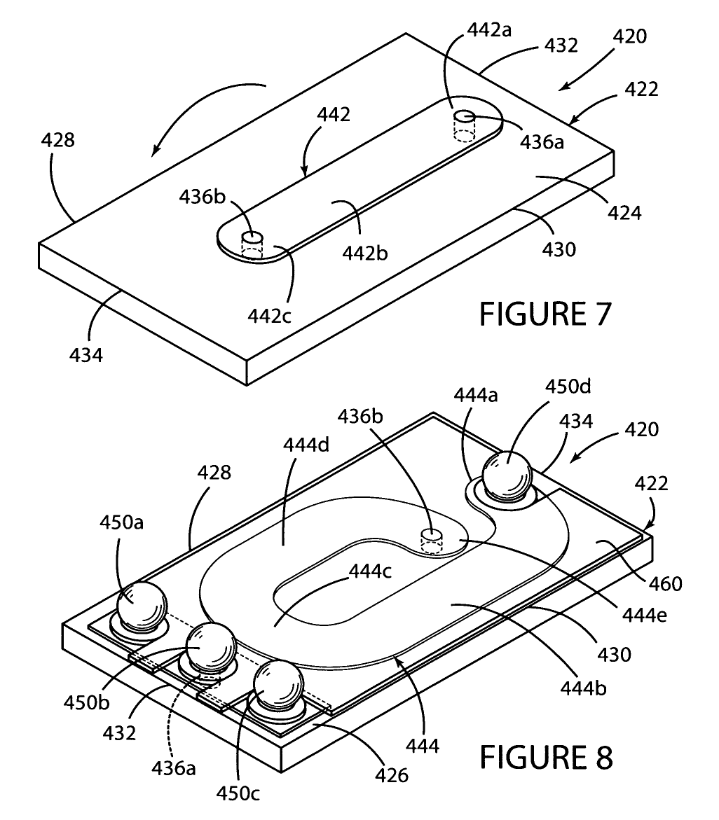

FIGS. 7 and 8 depict a fourth resonator embodiment 420 in accordance with the present invention.

Initially, and as described earlier with respect to the resonator embodiments 20, 220, and 320, resonator 420 likewise initially comprises a generally rectangularly-shaped substrate or block 422 which preferably has the same dimensions and composition as the substrate 22 and thus the earlier discussion and description with respect to substrate 22 is hereby incorporated herein by reference.

Substrate 422 includes a top surface 424 (FIG. 7), a bottom surface 426 (FIG. 8) adapted to face the top of the printed circuit board (not shown) on which the resonator 420 is adapted to be seated and direct surface mounted, and side surfaces defining long side/longitudinal peripheral edges 428 and 430 and short side/transverse peripheral edges 432 and 434 respectively.

In a manner similar to resonator embodiment 220, resonator 420 further includes a pair of elongate laser drilled through-holes defining conductive vias 436a and 436b which extend through the body/interior of the substrate 422 and terminate in respective apertures/openings in the top and bottom substrate surfaces 424 and 426. Vias 436a and 436b extend through the substrate 222 in a generally normal relationship relative to the top and bottom substrate surfaces 224 and 226.

In the embodiment of FIGS. 7 and 8, via 436a is generally centrally located and formed adjacent to and spaced from the short side substrate edge 432 while via 436b is generally centrally located and spaced from the short side substrate edge 434. Vias 436a and 436b are co-linearly aligned and are filled with the same Ag/Pd material as described with respect to vias 36a and 36b of resonator 20 and thus the earlier description is incorporated herein by reference.

In a manner similar to resonator embodiment 220, resonator 420 likewise includes conductive solder spheres/balls 450a, 450b, 450c, and 450d similar in size and composition to spheres 50a-50d and 250a-250d positioned and secured on the bottom surface 426 of substrate 422 and thus the earlier description is incorporated herein by reference. Specifically, spheres 450a, 450b, and 450c are aligned and extend along and adjacent the short side substrate edge 432 in a generally co-linear, spaced-apart relationship with sphere 450b overlying via 436a. Sphere 450d is generally centrally located along opposed short side substrate edge 434 in a relationship diametrically opposed to and co-linear with sphere 450b and via 436a.

Moreover, and as shown in FIGS. 7 and 8, each of the surfaces 424 and 426 of substrate 422 defines respective elongated conductive thick film resonator metallization pattern or strips 442 and 444 similar in composition to resonator metallization strips 42 and 44 of resonator 20 and resonator metallization strips 242 and 244 of resonator 220, the description of the composition of each of such strips thus being incorporated herein by reference as though fully described except as otherwise described below.

Resonator strip 242 is generally straight and is defined by one end 442a which is located adjacent substrate short side edge 432 and surrounds and is electrically coupled to the aperture/end of via 436a terminating in substrate surface 424; a generally straight central body segment 442b extending away from via 236b in a relationship and orientation generally centered on substrate 422 and parallel to long side substrate edges 428 and 430; and an opposite end 442c which surrounds and is electrically coupled to the end/aperture of via 436b terminating in substrate surface 224.

Resonator strip 444 on the bottom surface 426 of substrate 422 is generally curved and, more specifically, generally hook-shaped and is defined by one curvilinear proximal end 444a which surrounds and is electrically coupled to the sphere 450d; a generally straight segment 444b extending downwardly away from sphere 450d and proximal end 444a in a relationship and orientation generally parallel, adjacent to, and spaced from long side substrate edge 430; a curvilinearly-shaped base portion 444c disposed generally adjacent and spaced from substrate short side edge 432 and spheres 450a-450c; a straight portion/segment 444d which extends generally upwardly away from base portion 444d in a relationship spaced from, adjacent to, and generally parallel to long side substrate edge 428; and a terminal curvilinear end 444e which bends inwardly, surrounds, and is electrically coupled to the end/aperture of via 436b terminating in bottom surface 426. FIG. 8 shows glasscoat layer 460 similar to glasscoat layer 60 of resonator 20, formed over strip 444 and surface 426 of resonator 420.

Thus, in view of the above, and as explained above with resonator embodiments 20 and 220, it is understood that the formation and use of elongate resonator strips 442 and 444 on opposed substrate surfaces 424 and 426 in coupling electrical relationship with respective vias 436a and 436b defines a continuous elongate RF signal transmission line/pathway/strip/pattern extending through the resonator 420 which makes the resonator 420 particularly suited and adapted for low frequency applications, i.e., applications in the range below about 1.8 GHz.

Moreover, in the resonator embodiment 420 of FIGS. 7 and 8, respective resonator strips 442 and 444, as with the resonator strips 242 and 244 of resonator embodiment 220, have a width which is generally about one quarter the width of the resonator 420 or about twice the width of each of the resonator strips 42 and 44 of resonator embodiment 20. It is understood, of course, that increasing the width of the resonator strips results in a resonator with increased or heightened “Q” value since resistance decreases in proportion to an increase in the width of a conductive element.

In accordance with this embodiment of the invention and referring to FIGS. 7 and 8, the RF signal is adapted to pass successively from the RF input pad of, for example, the tank circuit of a voltage controlled oscillator (not shown) into and through either the solder sphere 450b or 450d which, depending upon the application, define respective RF signal input/output pads. In the application where the RF signal is inputted through the sphere 450d, the RF signal passes in a generally clockwise direction through the length of resonator strip 444; then upwardly through the interior of substrate 422 through via 436b; then through the length of resonator strip 442 on top surface 424; and then back down and through the interior of board substrate 422 through via 436a into sphere 450b and into the RF signal output pad (not shown) of a printed circuit board.

It is still further understood that numerous variations and modifications of the embodiments described above may be effected without departing from the spirit and scope of the novel features of the invention. No limitations with respect to the specific resonator structures illustrated herein are intended or should be inferred.

For example, it is understood that resonator performance is a function of a variety of factors such as: the length of the resonator strips; the width of the resonator strips; the shape of the resonator strips; the number of resonator strips; the location and relationship and position of the resonator strips relative to one another; the location and relationship between the respective signal and ground tap points on the respective strips; the value of the dielectric constant of the ceramic substrate material; the thickness of the ceramic substrate material; the length, diameter, location and/or number of vias extending through the substrate material; and the distance between the lid and substrate surface.

Thus, it is understood that the invention is not limited to the particular resonator and ground strip patterns depicted herein but also to any and all such variations of these patterns, vias, etc., which may be necessary for a particular application.

What is claimed is:

1. A ball grid array resonator comprising:
a ceramic substrate defining a first surface including a first elongate strip of conductive material thereon and an opposed second surface with a second elongate strip of conductive material thereon;
a first conductive via extending through said substrate and defining respective termination ends in said first and second surfaces in electrical coupling relationship with said respective first and second elongate strips of conductive material on said first and second surfaces respectively;
a first conductive ball on said first surface defining a ground pad; and
a second conductive ball on said first surface defining an RF signal input/output pad in electrical contact with said first strip of conductive material on said first surface.

2. The ball grid array resonator of claim 1, wherein each of the first and second surfaces includes first and second spiral-shaped strips of conductive material and a second conductive via extends through said substrate and defines respective termination ends in electrical contact with said second spiral-shaped strip of conductive material on said second surface and a third conductive ball on said first surface defining another RF input/output pad.

3. The ball grid array resonator of claim 1, wherein each of the first and second surfaces includes first and second hook-shaped strips of conductive material and a second conductive via extends through said substrate and defines respective termination ends in electrical contact with said second hook-shaped strip of conductive material on said second surface and a third conductive ball on said first surface defining another RF input/output pad.

4. The ball grid array resonator of claim 1, wherein each of the first and second surfaces includes first and second serpentine-shaped strips of conductive material and at least a second conductive via extends through said substrate and defines respective termination ends in electrical contact with said second serpentine-shaped strip of conductive material on said first and second surfaces respectively.

5. The ball grid array resonator of claim 1, wherein said first strip of conductive material is generally hook-shaped and the second strip of conductive material is generally straight, and a second conductive via extends through said substrate and defines respective termination ends in electrical contact with said second strip of conductive material and a third conductive ball on said first surface defining another RF input/output pad.

6. A resonator comprising:
a ceramic substrate defining opposed first and second surfaces including respective first and second strips of conductive material having a width less than the width of said ceramic substrate, each of the first and second strips of conductive material defining first and second ends;
at least a first conductive via extending through said substrate and defining respective termination ends in said first and second surfaces in electrical coupling relationship with said first and second strips of conductive material;
at least a second conductive via extending through said substrate and defining respective termination ends in said first and second surfaces, one of the termination ends being in electrical coupling relationship with said second strip of conductive material;
at least a first conductive pad on said first surface in electrical coupling relationship with said first strip of conductive material; and
at least a second conductive pad on said first surface in electrical coupling relationship with said second conductive via.

7. The resonator of claim 6, wherein at least one of the first and second strips of conductive material is elongate and spiral-shaped.

8. The resonator of claim 7, wherein both of the first and second strips of conductive material are elongate and spiral-shaped.

9. The resonator of claim 6, wherein at least one of the first and second strips of conductive material is elongate and generally hook-shaped.

10. The resonator of claim 9 wherein both of the first and second strips of conductive material are elongate and generally hook-shaped.

11. The resonator of claim 6, wherein at least one of the first and second strips of conductive material is elongate and generally serpentine-shaped.

12. The resonator of claim 11, wherein both of the first and second strips of conductive material are elongate and generally serpentine-shaped.

13. The resonator of claim 6, wherein said first and second conductive pads are defined by first and second conductive balls.

14. A resonator comprising:
a ceramic substrate including opposed top and bottom outer surfaces;
an RF signal transmission line defined by the combination of a first elongated strip of conductive material formed on the top surface, a second elongate strip of conductive material formed on the bottom surface, and a conductive via extending through the substrate and interconnecting the first and second strips of conductive material;
an RF signal input/output pad on the bottom surface of the substrate in electrical coupling relationship with the second strip of conductive material thereon; and
a ground pad on the bottom surface of the substrate.

15. The resonator of claim 14 wherein the RF signal transmission line further comprises another conductive via extending through the substrate and in electrical coupling relationship with said first elongated strip of conductive material and another RF signal input/output pad on the bottom surface of the substrate in electrical coupling relationship with said second conductive via.

16. The resonator of claim 15 wherein at least one of the first and second strips of conductive material has a spiral, hook, or serpentine pattern.

17. The resonator of claim 16 adapted for use in the tank circuit of a voltage controlled oscillator.

18. The resonator of claim 17, wherein each of the RF signal input/output pads and the ground pad is a ball.
